(19) United States
(12) Patent Application Publication
(10) Pub. No.: US 2017/0098356 A1
(43) Pub. Date: Apr. 6, 2017

(54) Opening Sensor with Magnetic Field Detection

(71) Applicant: Google Inc., Mountain View, CA (US)

(72) Inventors: Andrew Dai, San Francisco, CA (US); Evan Witty, San Francisco, CA (US)

(21) Appl. No.: 14/876,042

(22) Filed: Oct. 6, 2015

(51) Int. Cl. G08B 13/24; G01R 33/00; G01R 33/02

(52) U.S. Cl. CPC G08B 13/2491; G01R 33/02; G01R 33/0023

(57) ABSTRACT

Systems and techniques are provided for an opening sensor with magnetic field detection. A current magnetic field vector based on a strength and direction of a magnetic field detected by a magnetometer of an opening sensor disposed at an entry point may be received. The current magnetic field vector may be compared to an initial magnetic field vector for the opening sensor. It may be determined that the current magnetic field vector differs from the initial magnetic field vector by a threshold amount or more. A signal may be generated indicating that the opening sensor has been tripped. The opening sensor may include a magnet in a separate housing from a magnetometer sensor comprising the magnetometer. The opening sensor may include a magnetometer unit with a magnet in the same housing as a magnetometer sensor.

### BACKGROUND

A sensor with a magnet and magnetometer may be used to provide an indication of whether an entry point is open or closed. The status of the entry point reported by the sensor may be used when determining what mode a security system can be put in, or whether or an alarm should generated. For example, a security system in an armed state that receives a signal from the sensor indicating that the entry point has been opened may generate alarm, as the opening of the entry point may indicate an attempted intrusion.

The magnet and magnetometer of the sensor may be separate physical components, and may need to be installed on an entry point in a specific configuration in order for the sensor to function properly. For example, a magnet may be installed on a door frame while the magnetometer is installed on the door, with minimum and maximum distances between the install points for each physical component. If the magnet and magnetometer are not aligned correctly, or placed so that they are too close together or too far apart when the entry point is in a closed position, the sensor may not correctly detect the position of the entry point. This may result in an open entry point being detected by the sensor as closed or a closed entry point being detected by the sensor as open. Improper installation of the magnet and magnetometer may render the sensor less useful to a security system. A separate magnet may be used to tamper with or fool the sensor, preventing an open entry point from being detected.

### BRIEF SUMMARY

According to an implementation of the disclosed subject matter, a current magnetic field vector based on a strength and direction of a magnetic field detected by a magnetometer of an opening sensor disposed at an entry point may be received. The current magnetic field vector may be compared to an initial magnetic field vector for the opening sensor. It may be determined that the current magnetic field vector differs from the initial magnetic field vector by a threshold amount or more. A signal may be generated indicating that the opening sensor has been tripped.

The opening sensor may include a magnet separate from a housing for a magnetometer sensor comprising the magnetometer. The opening sensor may include a magnetometer unit with a magnet in the same housing as a magnetometer sensor. The initial magnetic field vector may be based on a strength and direction of a magnetic field detected by the magnetometer when the entry point is closed. The magnetic field may include a magnetic field from a magnet of the opening sensor and a geomagnetic field in the region of the magnet of the opening sensor.

The current magnetic field vector may be based on a strength and direction of a magnetic field detected by the magnetometer when the entry point is open. The current magnetic field vector may include a magnetic field from a magnet of the opening sensor, the local geomagnetic field, and a magnetic field from a second magnet.

To determine that the current magnetic field vector differs from the initial magnetic field vector by a threshold amount, it may be determined that the magnitude of the current magnetic field vector differs from the magnitude of the initial magnetic field vector by a threshold amount, or it may be determined that the direction of the current magnetic field vector differs from the direction of the initial magnetic field vector by a threshold amount.

The entry point may include a portion that has a magnetic permeability different than the magnetic permeability of air. The initial magnetic field vector may be based on a strength and direction of a magnetic field from a magnet of the opening sensor and the geomagnetic field when the entry point is closed and a portion of the magnetic field from the magnet travels through a portion of the entry point with a magnetic permeability different than the magnetic permeability of air before reaching the magnetometer. The current magnetic field vector may be based on a strength and direction of a magnetic field from the magnet of the opening sensor and the geomagnetic field when the entry point is open and the portion of the magnetic field from the magnet travels through the air before reaching the magnetometer.

A magnet may be affixed to a first portion of an entry point. A magnetometer and a communications chipset may be in a housing that may be affixed to a second portion of the entry point. The magnetometer may be a 3-axis magnetic sensor that may determine the strength and direction of a total magnetic field at the location of the magnetometer. The communication chipset may transmit the magnetic field vector to a computing device of a smart home environment.

The magnet may not need to be aligned with the housing including the magnetometer when the first housing is affixed to the first portion of the entry point and the housing is affixed to the second portion of the entry point. The magnetometer may generate a magnetic field vector based on the detected total magnetic field. A processor may compare an initial magnetic field vector based on a detected total magnetic field when the entry point is closed with a current magnetic field vector based on a current detected total magnetic field.

A magnet may be in a housing that may be affixed to a first portion of an entry point. A magnetometer and a communications chipset may be in the housing. The magnetometer may be a 3-axis magnetic sensor that may determine the strength and direction of a total magnetic field at the location of the magnetometer. The communication chipset may transmit the magnetic field vector to a computing device of a smart home environment.

The housing may be affixed to the first portion of the entry point with a pole of the magnet directed at a second portion of the entry point. The housing may be affixed to the first portion of the entry point such that a portion of the magnetic field from the magnet travels through the second portion of the entry point before reaching the magnetometer when the entry point is closed and travels through the air before reaching the magnetometer when the entry point is open. The magnetometer may generate a magnetic field vector based on the detected total magnetic field. A processor may compare an initial magnetic field vector based on a detected total magnetic field when the entry point is closed with a current magnetic field vector based on a current detected total magnetic field.

According to an embodiment of the disclosed subject matter, a means for receiving a current magnetic field vector based on a strength and direction of a magnetic field detected by a magnetometer of an opening sensor disposed at an entry point, a means for comparing the current magnetic field vector to an initial magnetic field vector for the opening sensor, a means for determining that the current magnetic field vector differs from the initial magnetic field vector by at least a threshold amount, a means for generating a signal indicating that the opening sensor has been tripped, a means for determining that the magnitude of the current magnetic field vector differs from the magnitude of the initial magnetic field vector by a threshold amount, and a means for determining that the direction of the current magnetic field vector differs from the direction of the initial magnetic field vector by a threshold amount, are included.

Additional features, advantages, and implementations of the disclosed subject matter may be set forth or apparent from consideration of the following detailed description, drawings, and claims. Moreover, it is to be understood that both the foregoing summary and the following detailed description provide examples of implementations and are intended to provide further explanation without limiting the scope of the claims.

### BRIEF DESCRIPTION OF THE DRAWINGS

The accompanying drawings, which are included to provide a further understanding of the disclosed subject matter, are incorporated in and constitute a part of this specification. The drawings also illustrate implementations of the disclosed subject matter and together with the detailed description serve to explain the principles of implementations of the disclosed subject matter. No attempt is made to show structural details in more detail than may be necessary for a fundamental understanding of the disclosed subject matter and various ways in which it may be practiced.

FIG. 1 shows an example arrangement suitable for an opening sensor with magnetic field detection according to an implementation of the disclosed subject matter.

FIG. 2 shows an example system suitable for opening sensor with magnetic field detection according to an implementation of the disclosed subject matter.

FIG. 3 shows an example installation of an opening sensor with magnetic field detection according to an implementation of the disclosed subject matter.

FIG. 4 shows an example of magnetic field detection by an opening sensor with magnetic field detection according to an implementation of the disclosed subject matter.

FIG. 5 shows an example of magnetic field detection by an opening sensor with magnetic field detection according to an implementation of the disclosed subject matter.

FIG. 6 shows an example arrangement suitable for an opening sensor with magnetic field detection according to an implementation of the disclosed subject matter.

FIG. 7 shows an example system suitable for opening sensor with magnetic field detection according to an implementation of the disclosed subject matter.

FIG. 8 shows an example installation an opening sensor with magnetic field detection according to an implementation of the disclosed subject matter

FIG. 9 shows an example of magnetic field detection by an opening sensor with magnetic field detection according to an implementation of the disclosed subject matter.

FIG. 10 shows an example of magnetic field detection by an opening sensor with magnetic field detection according to an implementation of the disclosed subject matter.

FIGS. 11A-B show an example of magnetic field vectors detected by an opening sensor with magnetic field detection.

FIGS. 12A-B show an example of magnetic field vectors detected by an opening sensor with magnetic field detection.

FIG. 13 shows an example of a process suitable for opening sensor with magnetic field detection according to an implementation of the disclosed subject matter.

FIG. 14 shows an example sensor as disclosed herein.

FIG. 15 shows an example of a sensor network as disclosed herein.

FIG. 16 shows an example configuration of sensors, one or more controllers, and a remote system as disclosed herein.

FIG. 17 shows a computer according to an embodiment of the disclosed subject matter.

FIG. 18 shows a network configuration according to an embodiment of the disclosed subject matter.

### DETAILED DESCRIPTION

Sensors which use a separate magnet and magnetic field strength detector to monitor the status of entryways may be susceptible to tampering. Such a sensor may detect the strength of the magnetic field from the magnet, and may be tripped when the detected strength drops, indicating that the entryway has been opened, moving the magnet of the sensor away from the magnetic field strength detector. A second magnet may be introduced near the magnetic field strength detector. Since the sensor only trips when the magnetic field strength detector detects a drop in magnetic field strength, the second magnet may allow the entryway to be opened without tripping the sensor. This may make such sensors insecure. Further, in order for the sensor to function properly, the magnet may need to be installed at some specific distance from and with some specific alignment to the magnetic field strength detector, making correct installation difficult.

According to embodiments disclosed herein, an opening sensor with magnetic field detection may allow for the determination of whether a door or window may be open or ajar as part of an intelligent security system. The opening sensor may include a magnetometer which may sense the strength and direction of the total magnetic field, which may include the geomagnetic field and a magnetic field from any other magnetic sources, at its location. The opening sensor may also include a magnet. The magnetometer may be housed in a magnetometer sensor, which may be separate from the magnet, or both the magnet and magnetometer may be housed in a magnetometer unit. The opening sensor may be installed on an entry point, such as a door or window. An opening sensor with a separate magnetometer sensor and magnet may be installed with the magnet on either the moving or stationary portion of an entry point, and the magnetometer sensor on the other portion of the entry point, so that the magnetometer of the magnetometer sensor detects the magnetic field of the magnet. An opening sensor with only a magnetometer unit may be installed on either the moving or stationary portion of an entry point so that part of the magnetic field of the magnet passes through the other portion of the entry point before being detected by the magnetometer sensor. When an opening sensor is installed, the magnetometer may detect the strength and direction of the total magnetic field when the entry point is closed. An initial magnetic field vector indicating the strength and direction of the total magnetic field detected by the magnetometer may be transmitted to a computing device, such as a hub computing device of a smart home environment, by the opening sensor. The opening sensor may then transmit continual magnetic field vectors as detected at the magnetometer sensor. The hub computing device may determine whether any of the transmitted magnetic field vectors differ from the initial magnetic field vector enough to indicate that the entry point has been opened or the opening sensor is being tampered with.

An opening sensor as disclosed herein may include one or two physical components. A two component opening sensor may include a magnet and a magnetometer sensor, with the magnetometer sensor having a separate housing from the magnet. A one component opening sensor may include a magnetometer unit, which may include the magnetometer sensor and the magnet within the same housing. The magnetometer sensor may include a magnetometer, which may be any suitable device for detecting the strength and direction of a magnetic field, for example, a 3-axis magnetic sensor, such as an e-compass or a magnetometer. The magnetometer sensor may also include a microcontroller with a processor for controlling the operation of the magnetometer sensor. The processor may send a request for data from the magnetometer, which can then activate into a working mode in which it can gather and send data to the processor. The working mode may be powered by a power supply such as a battery and/or at least partly from energy received in connection with the query from the processor. For example, the magnetometer may receive power from an antenna that receives a query from a remote processor system, much as RFID devices receive and use power from queries. The magnetometer may detect the strength and direction of the magnetic field and send data regarding the sensed field, for example, as a magnetic field vector, to the processor. The processor may receive the magnetic field vector and transmit it, using any suitable communications device in the magnetometer sensor, to a hub computing device for processing and comparison to the initial magnetic field vector. In some implementations, the processor of the opening sensor may store the initial magnetic field vector, and may compare subsequently detected magnetic field to the initial magnetic field vector locally to determine if the entry point has been opened or the opening sensor has been tampered with.

The installation of a two component opening sensor may involve placing the two physical components on separate parts of an entry point. For example, the magnet may be placed on the top of a door frame, while the magnetometer sensor may be placed at the top of the door, below the placement of the magnet. The magnetometer sensor and the magnet may be aligned. The magnet may be a permanent magnet, and may create a magnetic field that may be detected by the magnetometer in addition to the local geomagnetic field. Movement of the entry point, for example, opening the door, may result in the magnetic field vector detected by the magnetometer changing, for example, in both direction and strength as the door is opened further and the magnetometer sensor moves farther from the magnet.

The distance between the magnet and the magnetometer sensor, along with the strength of the magnet and the sensitivity of the magnetometer, for example, in the magnetometer, may influence data on magnetic field and or orientation reported by the magnetometer sensor and the functionality of the opening sensor. The magnet may be installed at any suitable distance from the magnetometer sensor, and at any suitable alignment, so long as the magnetometer sensor is able is able to detect the strength and direction of the magnetic field from the magnet, and changes to the strength and direction when the entry point is opened, in addition to the geomagnetic field. This may allow for simpler installation of the two component opening sensor, as the magnet may not need to be placed at a specific distance from or in a specific alignment with the magnetometer sensor.

The installation of a one component opening sensor may involve placing the one physical component, the magnetometer unit, on an entry point in a location where the magnetic field from the magnet passes through the portion of the entry point to which the magnetometer unit is not affixed. For example, the magnetometer unit may be affixed to a door so that part of the magnetic field from the magnet passes through the door frame before being detected by the magnetometer. The magnetometer unit may likewise be affixed to the door frame so that part of the magnetic field from the magnet travels through the door. When the entry point is opened, the part of the magnetic field that initially passed through a portion of the entry point may instead pass through the air, which may have a different magnetic permeability than the material of the entry point, resulting in a change to the strength and direction of the magnetic field detected by the magnetometer. The magnetometer unit may be installed so that one pole of the magnet in the magnetometer unit points towards the portion of the entry point to which the magnetometer unit is not affixed. For example, if the magnetometer unit is affixed to a door, the magnetometer unit may be oriented so that either the north or south pole of the magnet points towards the nearest part of the door frame.

After being installed on an entry point, an opening sensor may use the magnetometer to detect the magnetic field vector when the entry point is closed. This may be the initial magnetic field vector, or baseline, for the opening sensor. For example, after being installed on a door, either a one or two component opening sensor may detect the magnetic field vector with the door closed. The initial magnetic field vector may be stored on the opening sensor, for example, in an on-board computer readable storage, and/or may be transmitted to and stored by a hub computing device of a smart home environment, which may associate the initial magnetic field vector with the opening sensor and the entry point on which the opening sensor is installed.

The opening sensor may monitor the strength and direction of the magnetic field as detected by the magnetometer. The opening sensor may monitor the magnetic field continuously, or at specified intervals. For example, the processor of the opening sensor may request data from the magnetometer at any suitable time. The magnetometer may provide a magnetic field vector for the total magnetic field as detected the magnetometer. The total magnetic field may be the magnetic field generated by the magnet, which may be in the same housing as or separate from the magnetometer, along with the geomagnetic field and any other magnetic field that may be introduced, for example, by a magnet being used to tamper with the opening sensor.

The detected magnetic field vectors from the magnetometer may be compared with the initial magnetic field vector. For example, a processor of the opening sensor may compare magnetic field vectors received from the magnetometer to the initial magnetic field vector stored in on-board computer readable storage, or magnetic field vectors may be transmitted by the opening sensor to the hub computing device for comparison with the initial magnetic field vector for that opening sensor.

Variance between the detected magnetic field vector and the initial magnetic field vector, due to a change in strength, direction, or both, of the total magnetic field, may indicate that the entry point has been opened or the opening sensor is being tampered with. For example, a magnetic field vector detected by a two component opening sensor that differs from the initial magnetic field vector for that opening sensor may indicate that that entry point has been opened. The opening of the entry point may move the magnet farther away from the magnetometer, resulting in a weaker total magnetic field, and change the orientation of the magnetometer to the magnet, resulting in a change of direction of the magnetic field vector. A magnetic field vector detected by a one component opening sensor that differs from the initial magnetic field vector for that opening sensor may indicate that that entry point has been opened. The opening of the entry point may move the magnet and magnetometer away from the material of a portion of the entry point, resulting in the magnetic field reaching the magnet through a material with different magnetic permeability. For example, the initial magnetic field vector may be detected based on the magnetic field of the magnet reaching the magnetometer through the wood of a door frame. When the door is opened, the opening sensor, with both magnet and magnetometer, may travel with the door away from the door frame. The magnetic field from the magnet may then reach the magnetometer through the air, which may have a different magnetic permeability than the wood of the door frame. This may change the total magnetic field detected by the magnetometer, resulting in a magnetic field vector that differs from the initial magnetic field vector for the sensor.

Variance in the detected magnetic field vector may also indicate that another magnet, and magnetic field, has been introduced near the opening sensor. For example, the initial magnetic field vector may be based on the magnetometer's detection of the total magnetic field with the entry point closed, including the magnetic field from the magnet and the geomagnetic field. If the entry point remains closed, but the magnetometer detects a magnetic field vector that differs from the initial magnetic field vector, this may indicate the introduction of another magnetic field. For example, someone may attempt to tamper with the opening sensor by introducing a second magnet on the other side of the entry point from the opening sensor. The magnetic field from the second magnet may be detected by the magnetometer along with the magnetic field from the magnet of the opening sensor and the geomagnetic field. This may change the total magnetic field detected by the magnetometer, resulting in a magnetic field vector that differs from the initial magnetic field vector.

When a variance is detected, the opening sensor or hub computing device may take appropriate action. For example, a variance detected by the opening sensor may result in a signal being transmitted to the hub computing device, indicating that the opening sensor has been tripped, and a variance detected by the hub computing device may also result in a signal to other components of the hub computing device the opening sensor has been tripped. The hub computing device may then sound an alarm, notify a user of the smart home environment, for example, through a computing device belonging to a user or through output elements, such as screen or speakers, of the smart home environment, notify appropriate parties such as a security company or law enforcement, or may ignore the tripping of the opening sensor if, for example, the alarm system of the smart home environment is set to a low security mode.

The processor of the opening sensor, or the hub computing device, may be able to determine if variance in the detected magnetic field from the initial magnetic field vector indicates either an opening of the entry point or an attempt to tamper with the opening sensor. For example, very small variances, or variances that appear and disappear quickly, may be ignored, as they may be due to vibration of the entry point and opening sensor, for example, from passing traffic or the settling of a foundation. The opening sensor may only be tripped when the variance in the magnetic vector exceeds some threshold, indicating that the variance is not transient. The opening sensor or hub computing device may also attempt to determine the source of the variance between the initial magnetic field vector and a detected magnetic field vector. For example, the hub computing device may use several subsequent magnetic field vectors received from an opening sensor to determine, based on the way in which the magnetic field vector changes over time, whether the entry point is being opened, or whether a second magnet has been placed near the magnetometer.

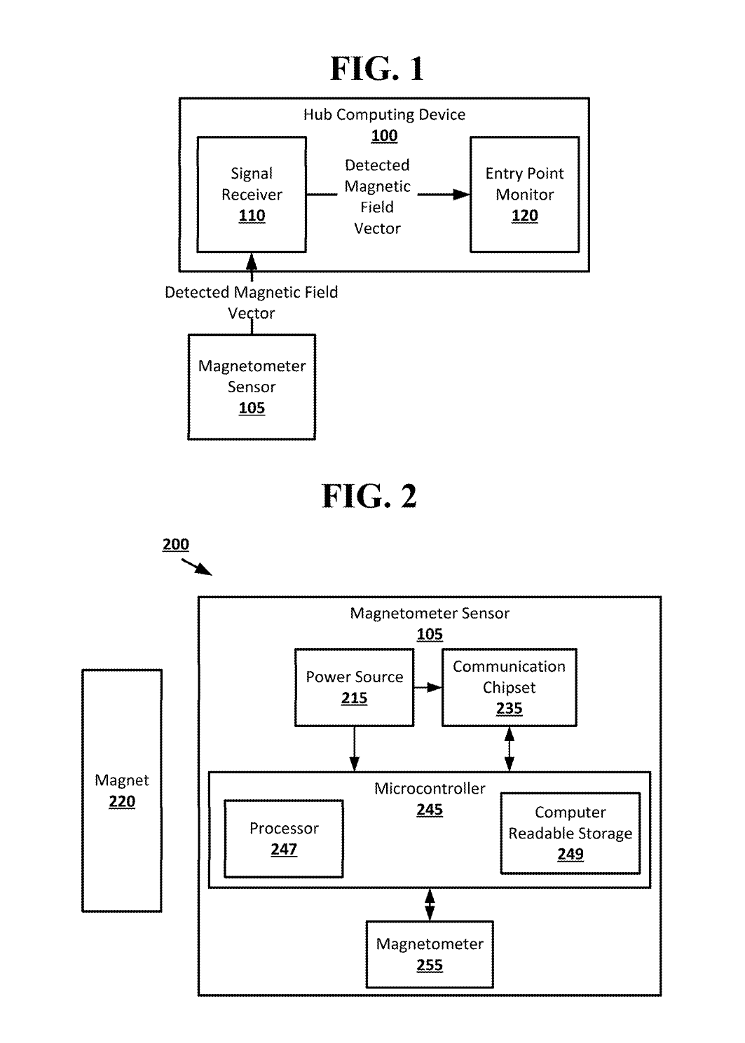

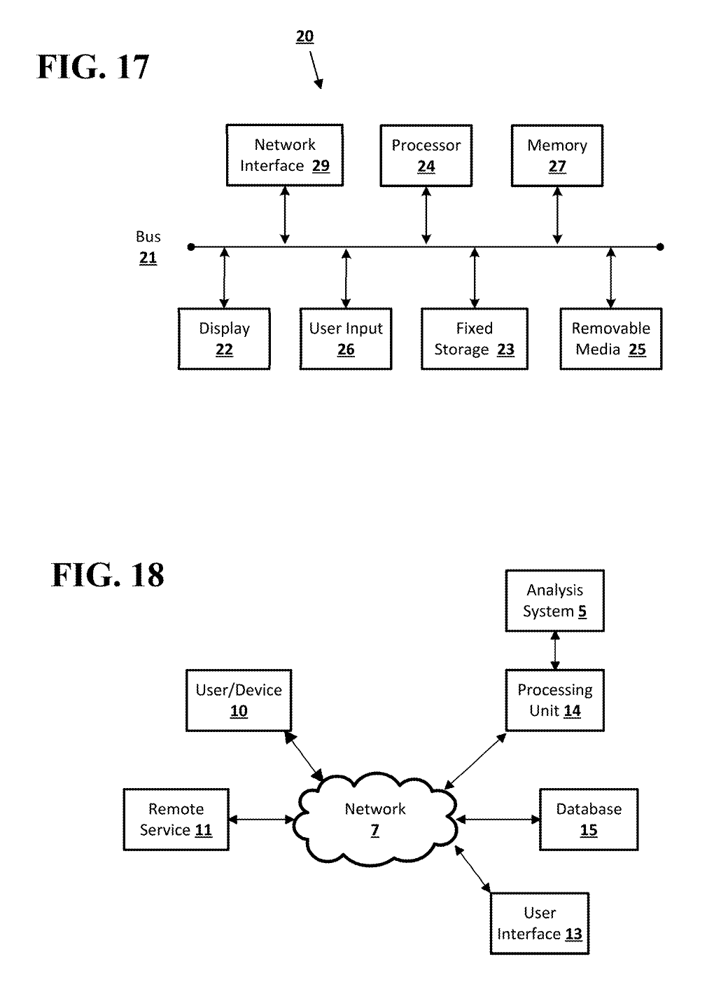

FIG. 1 shows an example arrangement suitable for an opening sensor with magnetic field detection according to an implementation of the disclosed subject matter. A hub computing device 100 may include a signal receiver 110 and an entry point monitor 120. The hub computing device 100 may be any suitable device, such as, for example, a computer 20 as described in FIG. 17, for implementing the signal receiver 110, the occupancy estimator 120, the mode selector 130, and storage 140. The hub computing device 100 may be, for example, a controller 73 as described in FIG. 15. The hub computing device 100 may be a single computing device, or may include multiple connected computing devices, and may be, for example, a smart thermostat, other smart sensor, smartphone, tablet, laptop, desktop, smart television, smart watch, or other computing device that may be able to act as a hub for a smart home environment, which may include a security system and automation functions. The smart home environment may be controlled from the hub computing device 100. The hub computing device 100 may also include a display. The signal receiver 110 may be any suitable combination of hardware or software for receiving signals generated by sensors that may be part of the smart home environment and may be connected to the hub computing device 100. The entry point monitor 120 may be any suitable combination of hardware and software monitoring the status of entry points within the smart home environment based on signals generated by opening sensors, such as an opening sensor including a magnetometer sensor 105.

The hub computing device 100 may be any suitable computing device for acting as the hub of a smart home environment. For example, the hub computing device 100 may be a smart thermostat, which may be connected to various sensors throughout an environment as well as to various systems within the environment, such as HVAC systems, or it may be another device within the smart home environment. The hub computing device 100 may include any suitable hardware and software interfaces through which a user may interact with the hub computing device 100. For example, the hub computing device 100 may include a touchscreen display, or may include web-based or app based interface that can be accessed using another computing device, such as a smartphone, tablet, or laptop. The hub computing device 100 may be located within the same environment as the smart home environment it controls, or may be located offsite. An onsite hub computing device 100 may use computation resources from other computing devices throughout the environment or connected remotely, such as, for example, as part of a cloud computing platform.

The hub computing device 100 may include a signal receiver 110. The signal receiver 110 may be any suitable combination of hardware and software for receiving signals from sensors connected to the hub computing device 100. For example, the signal receiver 110 may receive signals from any sensors distributed throughout a smart home environment, either individually or as part of sensor devices. The signal receiver 110 may receive any suitable signals from the sensors, including, for example, audio and video signals, signals indicating light levels, signals indicating detection or non-detection of motion, signals indicating whether entryways are open, closed, opening, closing, or experiencing any other form of displacement or tampering, such as magnetic field vectors detected by the magnetometer of the magnetometer sensor 105, which may be part of a two component opening sensor, signals indicating the current climate conditions within and outside of the environment, smoke and carbon monoxide detection signals, and signals indicating the presence or absence of occupants in the environment based on Bluetooth or WiFi signals and connections from electronic devices associated with occupants or fobs carried by occupants. The signal receiver 110 may pass received signals to other components of the hub computing device 100 for further processing, such as, for example, detection of tripped opening sensors. The signal receiver 110 may also be able to receive, or to associate with a received signal, an identification for the sensor from which the signal was received. This may allow the signal receiver 110 to distinguish which signals are being received from which sensors throughout the smart home environment. The signal receiver 110 may filter signals based on the type of sensor that generated the signal. For example, the signal receiver may send only signals generated by opening sensors to the entry point monitor 120.

The hub computing device 100 may include an entry point monitor 120. The entry point monitor 120 may be any suitable combination of hardware and software for receiving magnetic field vectors generated by the magnetometer of opening sensors and determining if there is any variance from the initial magnetic field vectors of the opening sensors, indicating that an entry point is being opened or an opening sensor is being tampered with. The entry point monitor 120 may receive magnetic field vectors from the opening sensors through the signal receiver 110. When the entry point monitor 120 determines that an entry point is being opened or an opening sensor is being tampered with, the entry point monitor 120 may generate any suitable signal indicating that an opening sensor has been tripped. The signal may include an identity of the opening sensor or entry point at which the trip occurred, and may be sent to any suitable component of the hub computing device 100, which may then take any suitable action. For example, the hub computing device 100 may sound an alarm, notify a user of the hub computing device or another appropriate party, or may take no action depending, for example, on a current security setting of the smart home environment.

The entry point monitor 120 may compare magnetic field vectors in any suitable manner, and may perform any suitable evaluation of any number of magnetic field vectors from an opening sensor. For example, the entry point monitor 120 may evaluate a series of magnetic field vectors from an opening sensor over time to determine, for example, if variance between the magnetic field vectors and the initial magnetic field vector indicates that the entry point monitored by the opening sensor is being opened or if a second magnet has been introduced near the opening sensor. The entry point monitor 120 may store the initial magnetic field vectors from the opening sensors when the opening sensors are installed. The initial magnetic field vectors may be stored, for example, in any suitable computer readable storage that may be part of, or locally or remotely accessible to, the hub computing device 100.

In some implementations, the opening sensor may include an on-board processor which perform the comparison and evaluation of the magnetic field vectors. When an opening sensor determines that it has been tripped, the opening sensor may send an appropriate signal to the signal receiver 110, which may pass the signal along to any suitable component of the hub computing device 100. For example, the signal may be passed to the entry point monitor 120, which may then handle passing the signal on to appropriate component of the hub computing device 100 in order for the appropriate action to be taken.

FIG. 2 shows an example system suitable for opening sensor with magnetic field detection according to an implementation of the disclosed subject matter. An opening sensor 200 may include two separate physical components, a magnetometer sensor 105 and a magnet 220. The magnetometer sensor 105 may include a microcontroller 245 for a magnetometer 255, a power source 215, and a transceiver (e.g., using radio or another communications medium) represented by the communication chipset 235. The communication chipset may refer to hardware suitable for wired and/or wireless communications such as a Wifi, Thread, Ethernet, mesh network, or similar network connection. The microcontroller 245 may include a processor 247, a computer readable storage 249 that may be programmed with computer readable code. The microcontroller 245 may receive instructions (which may include configuration information and activation signals) from a controller, for example, controller 73 as described in FIG. 15, and/or a remote system such, for example, remote system 74 as described in FIG. 15. Similarly, the microcontroller 245 may communicate data generated by the magnetometer 255 to the controller 73, for example, the hub computing device 100, and/or the remote system 74 via the communication chipset 235. The magnetometer sensor 105 may refer to the magnetometer 255, microcontroller 245, power source 115, and the communication chipset 235 and may be housed together as a single unit. The magnetometer sensor 105 may receive power from any suitable power source 215, such as, for example, a lithium battery, an electrical outlet, or a wireless power supply. The magnetometer 255 may be any suitable device for detecting the strength and direction of a magnetic field, for example, 3-axis magnetic sensor, such as an e-compass or a magnetometer. The magnet 220 may be a permanent magnet of any suitable material inside of a housing of any suitable material that may not interfere with the magnetic field produced by the magnet.

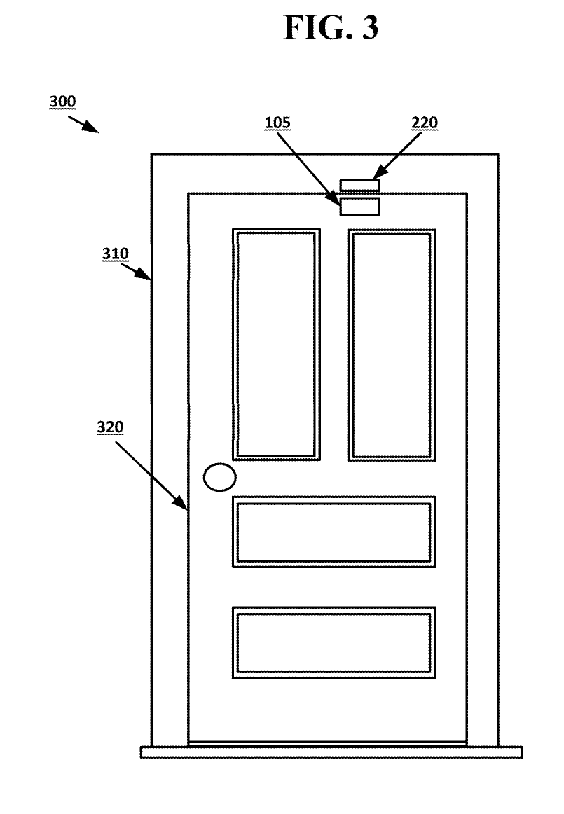

FIG. 3 shows an example installation of an opening sensor with magnetic field detection according to an implementation of the disclosed subject matter. The two component opening sensor 200 may be installed at an entry point 300, which may be, for example, a door including a door 320 installed in a door frame 310. The entry point 300 may be an interior entry point, for example, between rooms in a house, or an exterior entry point, for example, between the inside of a house and an outdoor area. The magnetometer sensor 105, including the magnetometer 255, may be affixed to the inside of the door 320 in any suitable manner, such as, for example, using touch fasteners, tape, adhesive, or fastening mechanisms such as screws or bolts. The magnetometer sensor 105 may be affixed at any suitable point on door 320 such that it is near a part of the door frame 310, including, for example, at the top of the door 320. The magnet 220 may be affixed to the door frame 210 in any suitable position near where the magnetometer sensor 105 is affixed to the door 320, so that the magnetometer 255 may be able to detect the magnetic field from the magnet 220. For example, if the magnetometer sensor 105 is affixed to the top of the door 320, the magnet 220 may be affixed to the top of the door frame 210 at a position vertically aligned with the magnetometer sensor 105. If the magnetometer sensor 105 is affixed to the side of the door 320, for example, the side from which the door 320 opens, the magnet 220 may be affixed to the door frame 310 horizontally aligned with magnetometer sensor 110. The magnet 220 may not need to be aligned directly with the magnetometer sensor 105, and may be placed at any suitable distance from the magnetometer sensor 105, so long as the total magnetic field detected by the magnetometer 255 includes both the geomagnetic field and the magnetic field from the magnet 220.

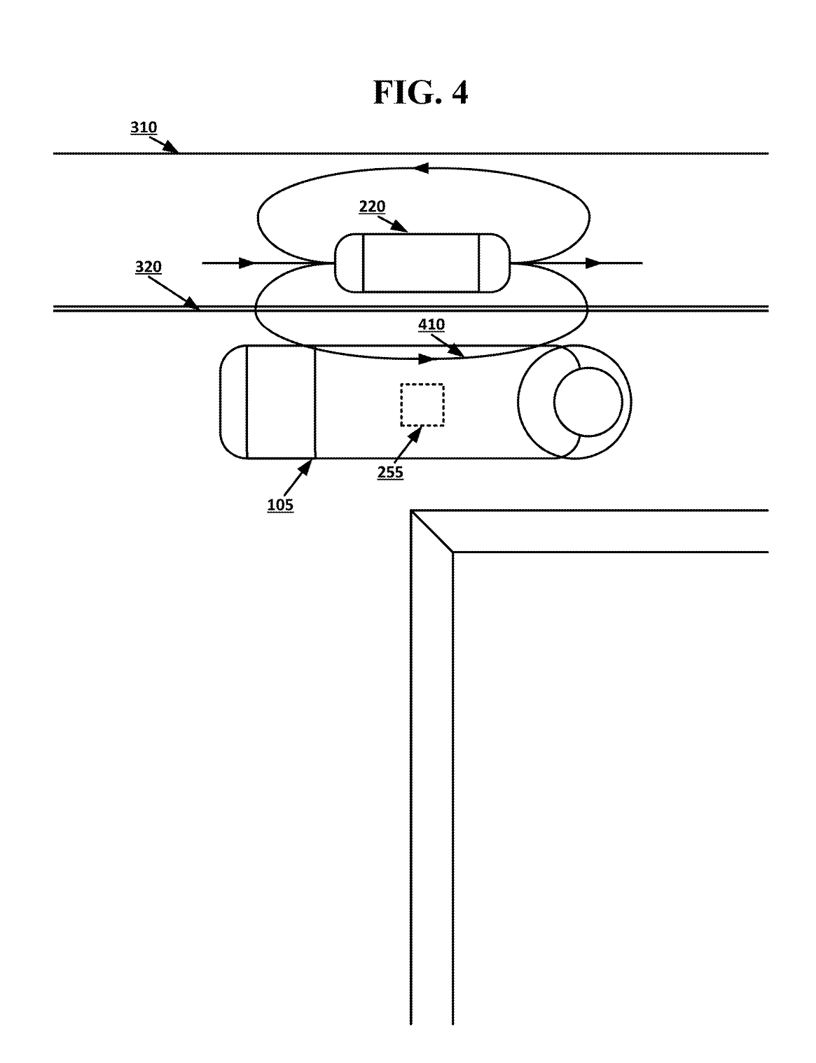

FIG. 4 shows an example of magnetic field detection by an opening sensor with magnetic field detection according to an implementation of the disclosed subject matter. The magnetometer sensor 105 may be placed at the top of the door 320. The magnet 220 may be installed on the door frame 310 close enough to the magnetometer sensor 105 that the magnetic field 410 of the magnet 220 may be detected by the magnetometer 255, housed within the magnetometer sensor 105. The magnet 220 may be placed at any suitable distance, with any suitable 3-dimensional displacement, from the magnetometer sensor 105, and may be oriented in any suitable manner with respect to the magnetometer sensor 105. For example, the magnet 220 may not need to align either vertically or horizontally with the magnetometer sensor 105 or any particular part of the sensor 105, may be affixed in front of or behind the magnetometer sensor 105, and/or may have its north and south poles oriented at any angle to the magnetometer sensor 105, so long as one of the magnet 220 and the magnetometer sensor 105 is on the door frame 310 and the other is on the door 320, and the magnetometer 255 can detect the magnetic field from the magnet 220 when the door 320 is closed.

After installation, the door 320 may be closed, and the magnetometer 255 may detect the total magnetic field. The magnetometer sensor 255 may report an initial magnetic field vector to the processor 247. The initial magnetic field vector may be stored in the computer readable storage medium 249, or may be sent to the signal receiver 110 of the hub computing device 100, for example, using the communication chipset 235. This may establish the initial magnetic field vector, or baseline, for the opening sensor 200 installed on the door 300. The magnetometer 255 may continue to detect the total magnetic field and report magnetic field vectors to the processor 247, where they may be evaluated for variance from the initial magnetic field vector on-board the magnetometer sensor 105 or be sent to the hub computing device 100 for evaluation. If the door 320 remains closed, and no additional magnetic fields are introduced around the opening sensor 200, the magnetic field vectors detected by the magnetometer 255 may be the same as, or have only minor or transient variations from, the initial magnetic field vector. As the door 320 is opened the total magnetic field at the magnetometer 255 may change. For example, the magnetometer sensor 105 mounted to the door may move farther from the magnet 220, resulting in the total magnetic field at the magnetometer 255 decreasing in strength as the door opens, and changing in direction as the angle between the magnet 220 and the magnetometer 255 changes. This may result in a magnetic field vector that differs from the initial magnetic field vector for the opening sensor 200. The variation may be detected, for example, by the entry point monitor 120 or the processor 247, resulting in a signal indicating that the opening sensor 200 has been tripped.

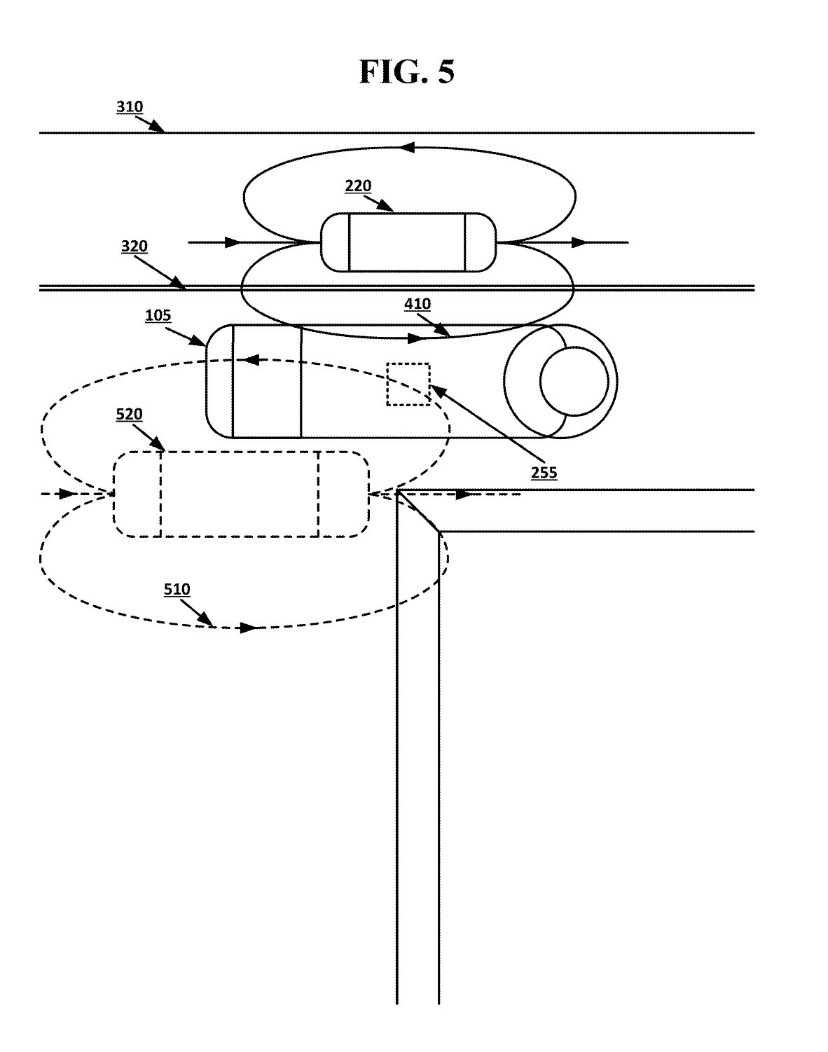

FIG. 5 shows an example of magnetic field detection by an opening sensor with magnetic field detection according to an implementation of the disclosed subject matter. With the door 320 closed, a second magnet 520, with a second magnetic field 510, may be placed on the opposite of the door from the opening sensor 200. For example, someone may attempt to use the second magnet 520 to tamper with or fool the opening sensor 200. The magnetometer 255 may detect a total magnetic field that includes the magnetic field 510 from the second magnet 520, the geomagnetic field, and the magnetic field 410 from the magnet 220. This may result in a magnetic field vector that differs from the initial magnetic field vector for the opening sensor 200, which may have only included the magnetic field 410 and the geomagnetic field. The variance in the magnetic field vector, including variance and strength and orientation may depend on the strength, orientation, and location of the second magnet 520 relative to the magnetometer 255 and the magnet 410. For example, in some orientations, the presence of the magnetic field 510 from the second magnet 520 may result in the magnetic field vector detected by the magnetometer 255 showing an increase in strength over the initial magnetic field, and in other orientations, a decrease in strength may be shown. The variation of the magnetic field vector from the initial magnetic field vector may be detected, for example, by the entry point monitor 120 or the processor 247, resulting in a signal indicating that the opening sensor 200 has been tripped. In some implementations, the signal may indicate that the opening sensor 200 has been tripped due to the presence of an additional magnet rather than the opening of the entry point.

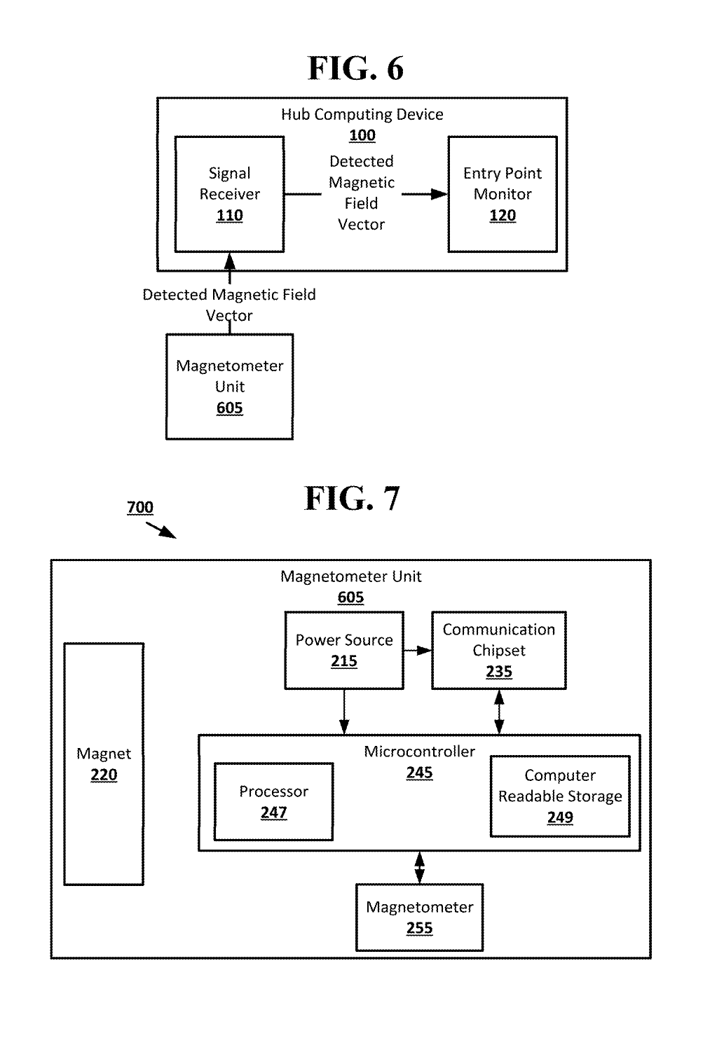

FIG. 6 shows an example arrangement suitable for an opening sensor with magnetic field detection according to an implementation of the disclosed subject matter. The signal receiver 110 may receive detected magnetic field vectors from a magnetometer unit 605 of a one component opening sensor. The signal receiver 110 may pass the magnetic field vectors to the entry point monitor 120, which may compare the magnetic field vectors to an initial magnetic field vector from the magnetometer unit 605. The magnetometer unit 605 may include the magnet 220 within the same housing as the magnetometer 255. The entry point monitor 120 may determine that the opening sensor has been tripped based on smaller variance of the magnetic field vector from the initial magnetic field vector, as having the magnet 220 in the same housing as the magnetometer 255 may result in smaller changes in the total magnetic field at the magnetometer sensor 255 when the entry point is opened.

FIG. 7 shows an example system suitable for opening sensor with magnetic field detection according to an implementation of the disclosed subject matter. An opening sensor 700 may include one physical component, a magnetometer unit 605. The magnetometer unit 605 may include the components of the magnetometer sensor 105, including the microcontroller 245 for the magnetometer 255, the power source 215, and the transceiver (e.g., using radio or another communications medium) represented by the communication chipset 235, the processor 247, and the computer readable storage 249. The magnetometer unit 605 may also include the magnet 220, which may be a permanent magnet of any suitable material, and may be located in the same housing as the components of the magnetometer sensor 105. The magnet 220 may be installed in the housing of the magnetometer unit 605 at any suitable distance from and orientation to the magnetometer 255.

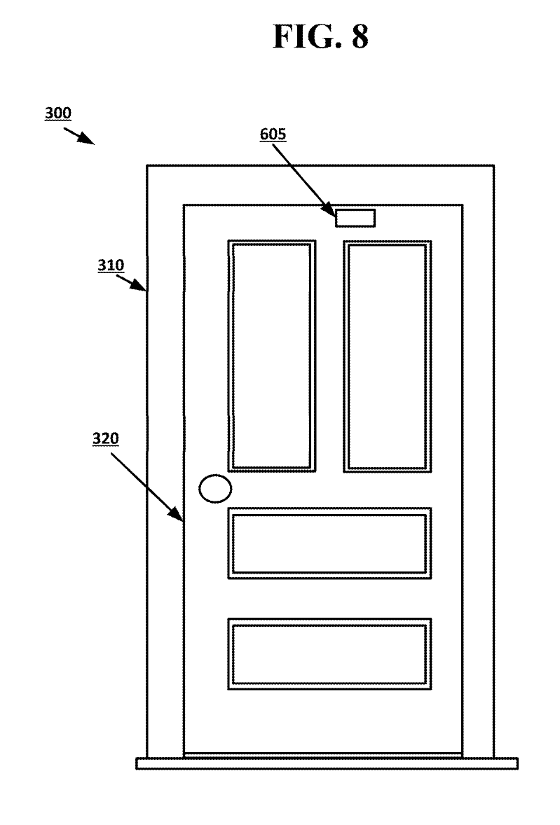

FIG. 8 shows an example installation of an opening sensor with magnetic field detection according to an implementation of the disclosed subject matter. The one component opening sensor 700 may be installed at the entry point 300, which may be, for example, a door including the door 320 installed in the door frame 310. The magnetometer unit 605, including the magnetometer 255 and magnet 220, may be affixed to the inside of the door 320 in any suitable manner, such as, for example, using touch fasteners, tape, adhesive, or fastening mechanisms such as screws or bolts. The magnetometer unit 605 may be affixed at any suitable point on door 320 such that it is near a part of the door frame 310, including, for example, at the top of the door 320. The magnetometer unit 605 may be oriented so that one of the poles of the magnet 220 points towards the door frame 310. This may result in the magnetic field from the magnet 220 passing through the door frame 310 before reaching the magnetometer 255.

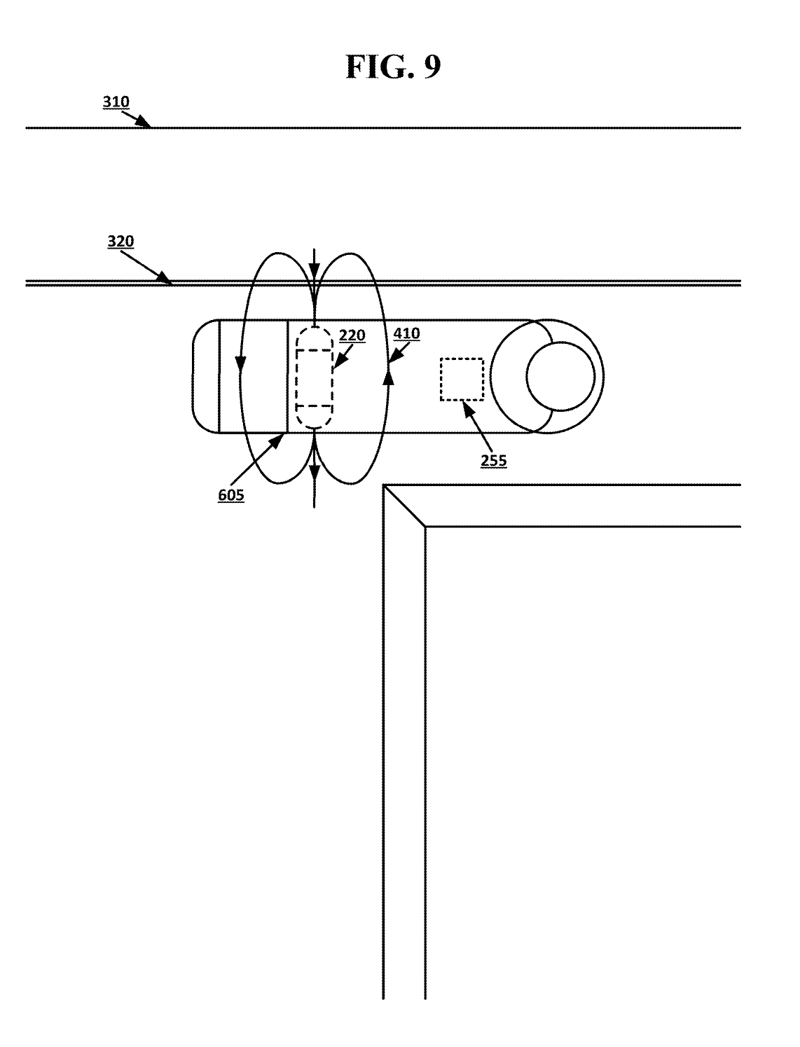

FIG. 9 shows an example of magnetic field detection by an opening sensor with magnetic field detection according to an implementation of the disclosed subject matter. The magnetometer unit 605 may be placed at the top of the door 320. The magnetic field 410 of the magnet 220 inside the magnetometer unit 605 may be detected by the magnetometer 255, housed within the magnetometer unit 605. Part of the magnetic field 410 may pass through the door frame 310 before being detected by the magnetometer 255.

After installation, the door 320 may be closed, and the magnetometer 255 may detect the total magnetic field. The magnetometer sensor 255 may report an initial magnetic field vector to the processor 247. The initial magnetic field vector may be stored in the computer readable storage medium 249, or may be sent to the signal receiver 110 of the hub computing device 100, for example, using the communication chipset 235. This may establish the initial magnetic field vector, or baseline, for the opening sensor 700 installed on the door 300. The magnetometer 255 may continue to detect the total magnetic field and report magnetic field vectors to the processor 247, where they may be evaluated for variance from the initial magnetic field vector on-board the magnetometer sensor 105 or be sent to the hub computing device 100 for evaluation. If the door 320 remains closed, and no additional magnetic fields are introduced around the opening sensor 200, the magnetic field vectors detected by the magnetometer 255 may be the same as, or have only minor or transient variations from, the initial magnetic field vector. The introduction of an additional magnet, such as the second magnet 520, may result in a change in the total magnetic field, as the magnetic field 510 may be added to the geomagnetic field and the magnetic field 410. This may result in the magnetometer 255 detecting a magnetic field vector that varies from the initial magnetic field vector for the opening sensor 700.

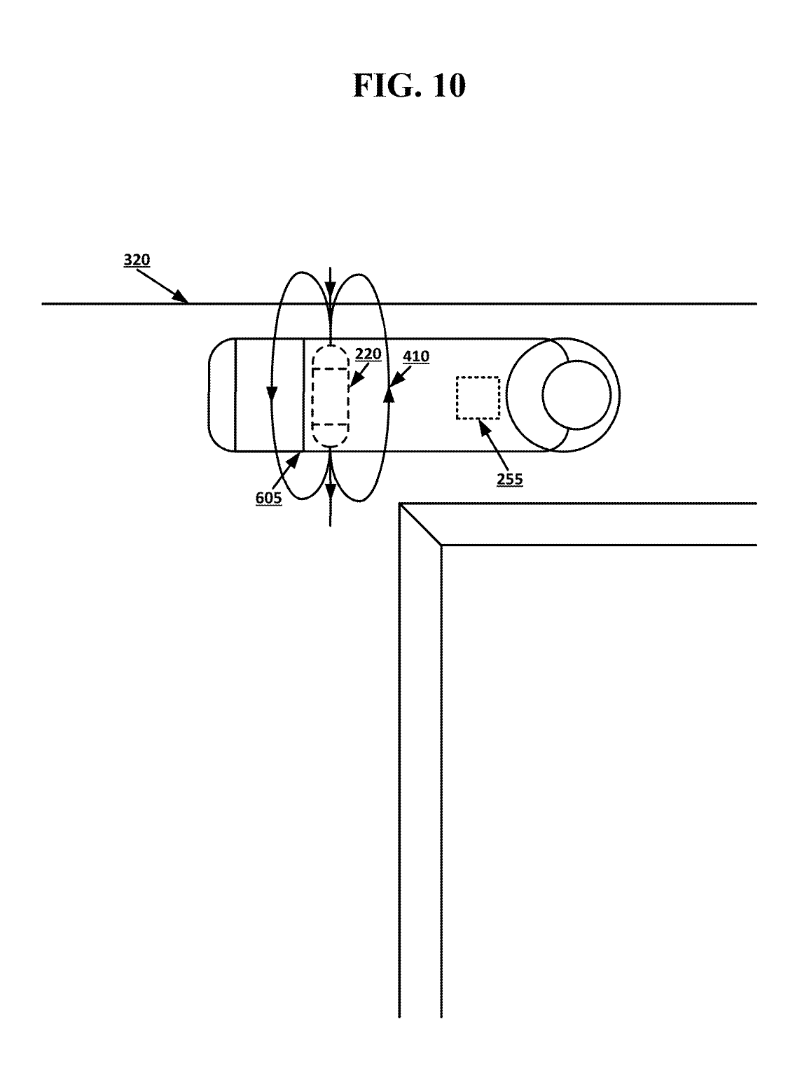

FIG. 10 shows an example of magnetic field detection by an opening sensor with magnetic field detection according to an implementation of the disclosed subject matter. As the door 320 is opened the total magnetic field at the magnetometer 255 may change. For example, the magnetic field 410 from the magnet 220 may reach the magnetometer 255 through the air, rather than through the material of the door frame 310, as the magnetometer unit 605 moves away from the door frame 310. The air may have a different magnetic permeability than the door frame 310, resulting in the total magnetic field at the magnetometer 255 changing. The strength and direction of the magnetic field 410 as detected at the magnetometer 255 may change as the magnetic permeability of the material through which the magnetic field 410 changes, from the material of the door frame 310 to air. This may result in a magnetic field vector that differs from the initial magnetic field vector for the opening sensor 700. The variation may be detected, for example, by the entry point monitor 120 or the processor 247, resulting in a signal indicating that the opening sensor 700 has been tripped.

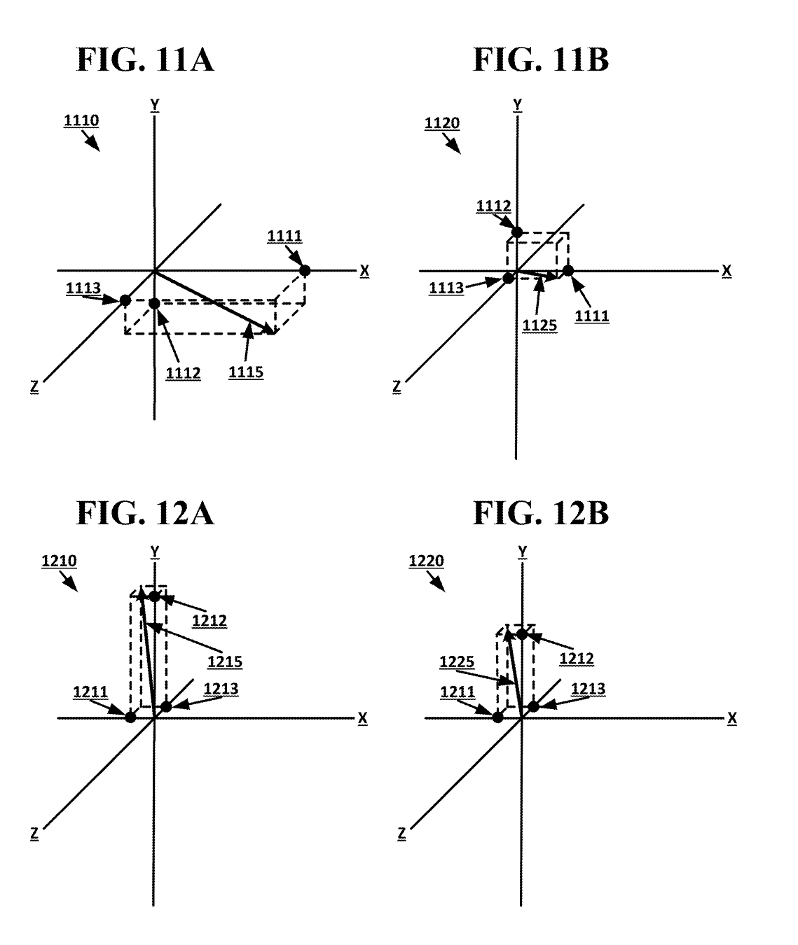

FIGS. 11A-B show an example of magnetic field vectors detected by an opening sensor with magnetic field detection. In FIG. 11A, graph 1110 may represent an initial magnetic field vector 1115 for a two component opening sensor, such as the opening sensor 200. The initial magnetic field vector 1115 may have three components, X component 1111, Y component 1112, and Z component 1113, which may be the detected 3-axis strengths of the total magnetic field at the magnetometer 255 in the magnetometer sensor 105 after installation on a closed entry point, such as the entry point 300. The initial magnetic field vector 1115 may represent the geomagnetic field and the magnetic field 410 at the magnetometer sensor 255. As long as the entry point 300 remains closed, and no other magnetic fields are introduced, the magnetometer 255 may continually detect a magnetic field vector similar or the same as the initial magnetic field vector 1115, indicating that the opening sensor 200 has not been tripped.

In FIG. 11B, graph 1120 may represent a magnetic field vector 1125 for a two component opening sensor, such as the opening sensor 200, after the second magnet 520 has been introduced near the magnetometer sensor 105. The magnetic field vector 1125 may have three components, X component 1121, Y component 1122, and Z component 1123, which may be the detected 3-axis strengths of the total magnetic field at the magnetometer 255 after introduction of the second magnet 520, with magnetic field 510. The magnetic field vector 1125 may represent the geomagnetic field, the magnetic field 410, and the magnetic field 510 at the magnetometer sensor 255. The magnetic field 510 may cause the X component 1121, Y component 1122, and Z component 1123, as detected by the magnetometer 255, to differ from the X component 1111, the Y component 1112, and the Z component 1113. The magnetic field vector 1125 may show variance from the initial magnetic field vector 1115, for example, having less magnitude, representing a weaker total magnetic field, due to the magnetic field 510 being oriented in the opposite direction of the magnetic field 410 at the magnetometer 255, and having a different direction, due to the location of the second magnet 520 relative to the magnet 220 and the magnetometer 255. This variation between the detected magnetic field vector 1125 and the initial magnetic field vector 1115 may be detected by, for example, the processor 247, or the entry point monitor 120, resulting in a signal indicating that the opening sensor 200 has been tripped.

FIGS. 12A-B show an example of magnetic field vectors detected by an opening sensor with magnetic field detection. In FIG. 12A, graph 1210 may represent an initial magnetic field vector 1215 for a one component opening sensor, such as the opening sensor 700. The initial magnetic field vector 1215 may have three components, X component 1211, Y component 1212, and Z component 1213, which may be the detected 3-axis strengths of the total magnetic field at the magnetometer 255 in the magnetometer unit 605 after installation on a closed entry point, such as the entry point 300. The initial magnetic field vector 1215 may represent the geomagnetic field and the magnetic field 410 at the magnetometer sensor 255, with some portion of the magnetic field 410 travelling through some material of the entry point 300, such as the wood of the door frame 310. As long as the entry point 300 remains closed, and no other magnetic fields are introduced, the magnetometer 255 may continually detect a magnetic field vector similar or the same as the initial magnetic field vector 1215, indicating that the opening sensor 700 has not been tripped.

In FIG. 12B, graph 1220 may represent a magnetic field vector 1225 for a two component opening sensor, such as the opening sensor 200, after the entry point 300 is opened. The magnetic field vector 1225 may have three components, X component 1221, Y component 1222, and Z component 1223, which may be the detected 3-axis strengths of the total magnetic field at the magnetometer 255 after the door 320 is opened, moving the magnetometer unit 605 away from the door frame 310. The magnetic field vector 1225 may represent the geomagnetic field and the magnetic field 410 at the magnetometer sensor 255, with some portion of the magnetic field 410 travelling through the air instead of the material, for example, wood, of the door frame 310. The change in material through which the magnetic field 410 travels before reaching the magnetometer 255 may cause the X component 1221, Y component 1222, and Z component 1223, as detected by the magnetometer 255, to differ from the X component 1211, the Y component 1212, and the Z component 1213. The magnetic field vector 1225 may show variance from the initial magnetic field vector 1215, for example, having less magnitude, representing a weaker total magnetic field, due to the air having a lower magnetic permeability than the material of the door frame 310. This variation between the detected magnetic field vector 1225 and the initial magnetic field vector 1215 may be detected by, for example, the processor 247, or the entry point monitor 120, resulting in a signal indicating that the opening sensor 700 has been tripped.

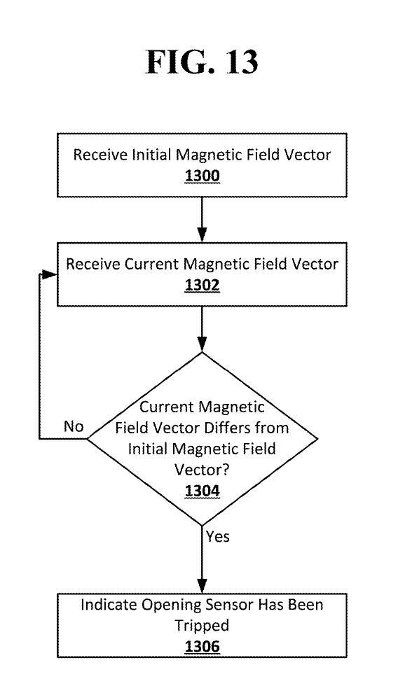

FIG. 13 shows an example of a process suitable for opening sensor with magnetic field detection according to an implementation of the disclosed subject matter. At 1300, an initial magnetic field vector may be received. For example, after an opening sensor, such as the opening sensor 200 or 700, is installed at entry point, such as the entry point 300, the magnetometer 255 may be used to detect the total magnetic field with the entry point 300 closed. The total magnetic field may be received, as a magnetic field vector, by the processor 247, or by the entry point monitor 120 through the signal receiver 110 of the hub computing device 100. The initial magnetic field vector may be received in any suitable format. For example, the initial magnetic field vector may be received as X, Y, Z coordinates or a magnitude and direction.

At 1302, a current magnetic field vector may be received. For example, after installation on the entry point 300, the opening sensor 200 or 700 may continuously monitor the entry point 300. The magnetometer 255 may take continuous readings of the total magnetic field, or may detect that total magnetic field at specific intervals or on-demand as requested by, for example, the processor 247. The magnetometer 255 may generate a current magnetic field vector, indicating the total magnetic field as of the most recent detection performed by the magnetometer 255. The current magnetic field vector may be received by, for example, processor 247, or by the entry point monitor 120 of the hub computing device 100.

At 1304, whether the current magnetic field vector differs from the initial magnetic field vector may be determined. For example, the current magnetic field vector may be compared to the initial magnetic field vector by the processor 247 or by the entry point monitor 120. If the current magnetic field vector is the same as or similar to the initial magnetic field vector, for example, the current magnetic field vector for an opening sensor 200 is similar to the initial magnetic field vector 1115, flow may proceed back to 1302. Otherwise, flow may proceed to 1306.

At 1306, that the opening sensor has been tripped may be indicated. For example, the current magnetic field vector received from the opening sensor 200 may differ from the initial magnetic field vector 1115 that was received from the opening sensor 200. This may indicate a change in the total magnetic field at the magnetometer 255, which may be indicative of the entry point 300 being opened, or the introduction of another magnetic field, such as the magnetic field 510 from the second magnet 520, near the magnetometer sensor 255 in an attempt to tamper with the opening sensor 200. The processor 247 or the entry point monitor 120 may generate a signal indicating that the opening sensor 200 has been tripped. The signal may be sent to an appropriate component of the hub computing device 100, which may handle the signal in any suitable manner, for example, sounding an alarm or notifying appropriate parties.

Implementations disclosed herein may use one or more sensors. In general, a “sensor” may refer to any device that can obtain information about its environment. Sensors may be described in terms of the type of information they collect. For example, sensor types as disclosed herein may include motion, smoke, carbon monoxide, proximity, temperature, time, physical orientation, acceleration, location, entry, presence, pressure, light, sound, and the like. A sensor also may be described in terms of the particular physical device that obtains the environmental information. For example, an accelerometer may obtain acceleration information, and thus may be used as a general motion sensor and/or an acceleration sensor. A sensor also may be described in terms of the specific hardware components used to implement the sensor. For example, a temperature sensor may include a thermistor, thermocouple, resistance temperature detector, integrated circuit temperature detector, or combinations thereof. A sensor also may be described in terms of a function or functions the sensor performs within an integrated sensor network, such as a smart home environment as disclosed herein. For example, a sensor may operate as a security sensor when it is used to determine security events such as unauthorized entry. A sensor may operate with different functions at different times, such as where a motion sensor is used to control lighting in a smart home environment when an authorized user is present, and is used to alert to unauthorized or unexpected movement when no authorized user is present, or when an alarm system is in an away (e.g., “armed”) state, or the like. In some cases, a sensor may operate as multiple sensor types sequentially or concurrently, such as where a temperature sensor is used to detect a change in temperature, as well as the presence of a person or animal. A sensor also may operate in different modes at the same or different times. For example, a sensor may be configured to operate in one mode during the day and another mode at night. As another example, a sensor may operate in different modes based upon a state of a home security system or a smart home environment, or as otherwise directed by such a system.

In general, a “sensor” as disclosed herein may include multiple sensors or sub-sensors, such as where a position sensor includes both a global positioning sensor (GPS) as well as a wireless network sensor, which provides data that can be correlated with known wireless networks to obtain location information. Multiple sensors may be arranged in a single physical housing, such as where a single device includes movement, temperature, magnetic, and/or other sensors. Such a housing also may be referred to as a sensor, a sensor device, or a sensor package. For clarity, sensors are described with respect to the particular functions they perform and/or the particular physical hardware used, when such specification is necessary for understanding of the embodiments disclosed herein.

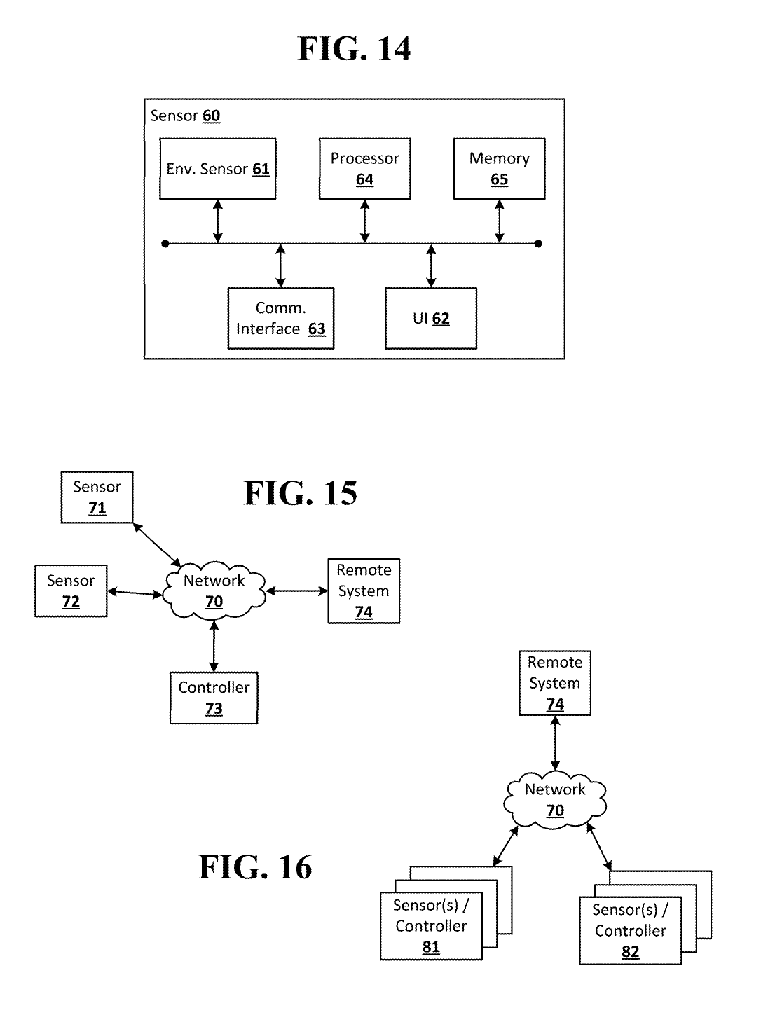

A sensor may include hardware in addition to the specific physical sensor that obtains information about the environment. FIG. 14 shows an example sensor as disclosed herein. The sensor 60 may include an environmental sensor 61, such as a temperature sensor, smoke sensor, carbon monoxide sensor, motion sensor, accelerometer, proximity sensor, passive infrared (PIR) sensor, magnetic field sensor, radio frequency (RF) sensor, light sensor, humidity sensor, pressure sensor, microphone, or any other suitable environmental sensor, that obtains a corresponding type of information about the environment in which the sensor 60 is located. A processor 64 may receive and analyze data obtained by the sensor 61, control operation of other components of the sensor 60, and process communication between the sensor and other devices. The processor 64 may execute instructions stored on a computer-readable memory 65. The memory 65 or another memory in the sensor 60 may also store environmental data obtained by the sensor 61. A communication interface 63, such as a Wi-Fi or other wireless interface, Ethernet or other local network interface, or the like may allow for communication by the sensor 60 with other devices. A user interface (UI) 62 may provide information and/or receive input from a user of the sensor. The UI 62 may include, for example, a speaker to output an audible alarm when an event is detected by the sensor 60. Alternatively, or in addition, the UI 62 may include a light to be activated when an event is detected by the sensor 60. The user interface may be relatively minimal, such as a liquid crystal display (LCD), light-emitting diode (LED) display, or limited-output display, or it may be a full-featured interface such as a touchscreen. Components within the sensor 60 may transmit and receive information to and from one another via an internal bus or other mechanism as will be readily understood by one of skill in the art. One or more components may be implemented in a single physical arrangement, such as where multiple components are implemented on a single integrated circuit. Sensors as disclosed herein may include other components, and/or may not include all of the illustrative components shown.

As a specific example, a sensor may include a magnetometer or opening sensor as illustrated by FIGS. 1-13 and described in further detail with respect to FIGS. 1-13.

In some configurations, two or more sensors may generate data that can be used by a processor of a system to generate a response and/or infer a state of the environment. For example, an ambient light sensor in a room may determine that the room is dark (e.g., less than 60 lux). A microphone in the room may detect a sound above a set threshold, such as 60 dB. The system processor may determine, based on the data generated by both sensors that it should activate one or more lights in the room. In the event the processor only received data from the ambient light sensor, the system may not have any basis to alter the state of the lighting in the room. Similarly, if the processor only received data from the microphone, the system may lack sufficient data to determine whether activating the lights in the room is necessary, for example, during the day the room may already be bright or during the night the lights may already be on. As another example, two or more sensors may communicate with one another. Thus, data generated by multiple sensors simultaneously or nearly simultaneously may be used to determine a state of an environment and, based on the determined state, generate a response.

Data generated by one or more sensors may indicate a behavior pattern of one or more users and/or an environment state over time, and thus may be used to “learn” such characteristics. For example, data generated by an ambient light sensor in a room of a house and the time of day may be stored in a local or remote storage medium with the permission of an end user. A processor in communication with the storage medium may compute a behavior based on the data generated by the light sensor. The light sensor data may indicate that the amount of light detected increases until an approximate time or time period, such as 3:30 PM, and then declines until another approximate time or time period, such as 5:30 PM, at which point there is an abrupt increase in the amount of light detected. In many cases, the amount of light detected after the second time period may be either below a dark level of light (e.g., under or equal to 60 lux) or bright (e.g., equal to or above 400 lux). In this example, the data may indicate that after 5:30 PM, an occupant is turning on/off a light as the occupant of the room in which the sensor is located enters/leaves the room. At other times, the light sensor data may indicate that no lights are turned on/off in the room. The system, therefore, may learn that occupants patterns of turning on and off lights, and may generate a response to the learned behavior. For example, at 5:30 PM, a smart home environment or other sensor network may automatically activate the lights in the room if it detects an occupant in proximity to the home. In some embodiments, such behavior patterns may be verified using other sensors. Continuing the example, user behavior regarding specific lights may be verified and/or further refined based upon states of, or data gathered by, smart switches, outlets, lamps, and the like.

Sensors as disclosed herein may operate within a communication network, such as a conventional wireless network, a mesh network (e.g., Thread), and/or a sensor-specific network through which sensors may communicate with one another and/or with dedicated other devices. In some configurations, one or more sensors may provide information to one or more other sensors, to a central controller, or to any other device capable of communicating on a network with the one or more sensors. A central controller may be general- or special-purpose. For example, one type of central controller is a home automation network, that collects and analyzes data from one or more sensors within the home. Another example of a central controller is a special-purpose controller that is dedicated to a subset of functions, such as a security controller that collects and analyzes sensor data primarily or exclusively as it relates to various security considerations for a location. A central controller may be located locally with respect to the sensors with which it communicates and from which it obtains sensor data, such as in the case where it is positioned within a home that includes a home automation and/or sensor network. Alternatively or in addition, a central controller as disclosed herein may be remote from the sensors, such as where the central controller is implemented as a cloud-based system that communicates with multiple sensors, which may be located at multiple locations and may be local or remote with respect to one another.

FIG. 15 shows an example of a sensor network as disclosed herein, which may be implemented over any suitable wired and/or wireless communication networks. One or more sensors 71, 72 may communicate via a local network 70, such as a Wi-Fi or other suitable network, with each other and/or with a controller 73. The controller may be a general- or special-purpose computer such as a smartphone, a smartwatch, a tablet, a laptop, etc. The controller may, for example, receive, aggregate, and/or analyze environmental information received from the sensors 71, 72. The sensors 71, 72 and the controller 73 may be located locally to one another, such as within a single dwelling, office space, building, room, or the like, or they may be remote from each other, such as where the controller 73 is implemented in a remote system 74 such as a cloud-based reporting and/or analysis system. In some configurations, the system may have multiple controllers 74 such as where multiple occupants' smartphones and/or smartwatches are authorized to control and/or send/receive data to or from the various sensors 71, 72 deployed in the home. Alternatively or in addition, sensors may communicate directly with a remote system 74. The remote system 74 may, for example, aggregate data from multiple locations, provide instruction, software updates, and/or aggregated data to a controller 73 and/or sensors 71, 72.

The sensor network shown in FIG. 15 may be an example of a smart-home environment. The depicted smart-home environment may include a structure, a house, office building, garage, mobile home, or the like. The devices of the smart home environment, such as the sensors 71, 72, the controller 73, and the network 70 may be integrated into a smart-home environment that does not include an entire structure, such as an apartment, condominium, or office space.

The smart home environment can control and/or be coupled to devices outside of the structure. For example, one or more of the sensors 71, 72 may be located outside the structure, for example, at one or more distances from the structure (e.g., sensors 71, 72 may be disposed outside the structure, at points along a land perimeter on which the structure is located, and the like. One or more of the devices in the smart home environment need not physically be within the structure. For example, the controller 73 which may receive input from the sensors 71, 72 may be located outside of the structure.

The structure of the smart-home environment may include a plurality of rooms, separated at least partly from each other via walls. The walls can include interior walls or exterior walls. Each room can further include a floor and a ceiling. Devices of the smart-home environment, such as the sensors 71, 72, may be mounted on, integrated with and/or supported by a wall, floor, or ceiling of the structure.

The smart-home environment including the sensor network shown in FIG. 15 may include a plurality of devices, including intelligent, multi-sensing, network-connected devices, that can integrate seamlessly with each other and/or with a central server or a cloud-computing system (e.g., controller 73 and/or remote system 74) to provide home-security and smart-home features. The controller may determine an intensity level of illumination for lights connected to the smart home system and/or a color or temperature for the lights. The smart-home environment may include one or more intelligent, multi-sensing, network-connected thermostats (e.g., “smart thermostats”), one or more intelligent, network-connected, multi-sensing hazard detection units (e.g., “smart hazard detectors”), and one or more intelligent, multi-sensing, network-connected entryway interface devices (e.g., “smart doorbells”). The smart hazard detectors, smart thermostats, and smart doorbells may be the sensors 71, 72 shown in FIG. 15.

For example, a smart thermostat may detect ambient climate characteristics (e.g., temperature and/or humidity) and may control an HVAC (heating, ventilating, and air conditioning) system accordingly of the structure. For example, the ambient client characteristics may be detected by sensors 71, 72 shown in FIG. 15, and the controller 73 may control the HVAC system (not shown) of the structure.

As another example, a smart hazard detector may detect the presence of a hazardous substance or a substance indicative of a hazardous substance (e.g., smoke, fire, or carbon monoxide). For example, smoke, fire, and/or carbon monoxide may be detected by sensors 71, 72 shown in FIG. 15, and the controller 73 may control an alarm system to provide a visual and/or audible alarm to the user of the smart-home environment.

As another example, a smart doorbell may control doorbell functionality, detect a person's approach to or departure from a location (e.g., an outer door to the structure), and announce a person's approach or departure from the structure via audible and/or visual message that is output by a speaker and/or a display coupled to, for example, the controller 73.

In some embodiments, the smart-home environment of the sensor network shown in FIG. 15 may include one or more intelligent, multi-sensing, network-connected wall switches (e.g., “smart wall switches”), one or more intelligent, multi-sensing, network-connected wall plug interfaces (e.g., “smart wall plugs”). The smart wall switches and/or smart wall plugs may be or include one or more of the sensors 71, 72 shown in FIG. 15. A smart wall switch may detect ambient lighting conditions, and control a power and/or dim state of one or more lights. For example, a sensor such as sensors 71, 72, may detect ambient lighting conditions, and a device such as the controller 73 may control the power to one or more lights (not shown) in the smart-home environment. Smart wall switches may also control a power state or speed of a fan, such as a ceiling fan. For example, sensors 72, 72 may detect the power and/or speed of a fan, and the controller 73 may adjust the power and/or speed of the fan, accordingly. Smart wall plugs may control supply of power to one or more wall plugs (e.g., such that power is not supplied to the plug if nobody is detected to be within the smart-home environment). For example, one of the smart wall plugs may control supply of power to a lamp (not shown).

In embodiments of the disclosed subject matter, a smart-home environment may include one or more intelligent, multi-sensing, network-connected entry detectors (e.g., “smart entry detectors”). Such detectors may be or include one or more of the sensors 71, 72 shown in FIG. 15. The illustrated smart entry detectors (e.g., sensors 71, 72) may be disposed at one or more windows, doors, and other entry points of the smart-home environment for detecting when a window, door, or other entry point is opened, broken, breached, and/or compromised. The smart entry detectors may generate a corresponding signal to be provided to the controller 73 and/or the remote system 74 when a window or door is opened, closed, breached, and/or compromised. In some embodiments of the disclosed subject matter, the alarm system, which may be included with controller 73 and/or coupled to the network 70 may not be placed in an away mode (e.g., “armed”) unless all smart entry detectors (e.g., sensors 71, 72) indicate that all doors, windows, entryways, and the like are closed and/or that all smart entry detectors are in an away mode. In some configurations, the system may arm if it can be determined that the distance the door (or window) is ajar is insubstantial (e.g., the opening is not wide enough for a person to fit through).

The smart-home environment of the sensor network shown in FIG. 15 can include one or more intelligent, multi-sensing, network-connected doorknobs (e.g., “smart doorknob”). For example, the sensors 71, 72 may be coupled to a doorknob of a door (e.g., doorknobs 122 located on external doors of the structure of the smart-home environment). However, it should be appreciated that smart doorknobs can be provided on external and/or internal doors of the smart-home environment.

The smart thermostats, the smart hazard detectors, the smart doorbells, the smart wall switches, the smart wall plugs, the smart entry detectors, the smart doorknobs, the keypads, and other devices of a smart-home environment (e.g., as illustrated as sensors 71, 72 of FIG. 15) can be communicatively coupled to each other via the network 70, and to the controller 73 and/or remote system 74 to provide security, safety, and/or comfort for the smart home environment.

A user can interact with one or more of the network-connected smart devices (e.g., via the network 70). For example, a user can communicate with one or more of the network-connected smart devices using a computer (e.g., a desktop computer, laptop computer, tablet, or the like) or other portable electronic device (e.g., a smartphone, a tablet, a key FOB, or the like). A webpage or application can be configured to receive communications from the user and control the one or more of the network-connected smart devices based on the communications and/or to present information about the device's operation to the user. For example, the user can view or change the mode of the security system of the home.

One or more users can control one or more of the network-connected smart devices in the smart-home environment using a network-connected computer or portable electronic device. In some examples, some or all of the users (e.g., individuals who live in the home) can register their mobile device and/or key FOBs with the smart-home environment (e.g., with the controller 73). Such registration can be made at a central server (e.g., the controller 73 and/or the remote system 74) to authenticate the user and/or the electronic device as being associated with the smart-home environment, and to provide permission to the user to use the electronic device to control the network-connected smart devices and the security system of the smart-home environment. A user can use their registered electronic device to remotely control the network-connected smart devices and security system of the smart-home environment, such as when the occupant is at work or on vacation. The user may also use their registered electronic device to control the network-connected smart devices when the user is located inside the smart-home environment.

Alternatively, or in addition to registering electronic devices, the smart-home environment may make inferences about which individuals live in the home and are therefore users and which electronic devices are associated with those individuals. As such, the smart-home environment may “learn” who is a user (e.g., an authorized user) and permit the electronic devices associated with those individuals to control the network-connected smart devices of the smart-home environment (e.g., devices communicatively coupled to the network 70), in some embodiments including sensors used by or within the smart-home environment. Various types of notices and other information may be provided to users via messages sent to one or more user electronic devices. For example, the messages can be sent via email, short message service (SMS), multimedia messaging service (MMS), unstructured supplementary service data (USSD), as well as any other type of messaging services and/or communication protocols.

A smart-home environment may include communication with devices outside of the smart-home environment but within a proximate geographical range of the home. For example, the smart-home environment may include an outdoor lighting system (not shown) that communicates information through the communication network 70 or directly to a central server or cloud-computing system (e.g., controller 73 and/or remote system 74) regarding detected movement and/or presence of people, animals, and any other objects and receives back commands for controlling the lighting accordingly.

The controller 73 and/or remote system 74 can control the outdoor lighting system based on information received from the other network-connected smart devices in the smart-home environment. For example, in the event that any of the network-connected smart devices, such as smart wall plugs located outdoors, detect movement at nighttime, the controller 73 and/or remote system 74 can activate the outdoor lighting system and/or other lights in the smart-home environment.

In some configurations, a remote system 74 may aggregate data from multiple locations, such as multiple buildings, multi-resident buildings, and individual residences within a neighborhood, multiple neighborhoods, and the like. In general, multiple sensor/controller systems 81, 82 as previously described with respect to FIG. 15 may provide information to the remote system 74 as shown in FIG. 16. The systems 81, 82 may provide data directly from one or more sensors as previously described, or the data may be aggregated and/or analyzed by local controllers such as the controller 73, which then communicates with the remote system 74. The remote system may aggregate and analyze the data from multiple locations, and may provide aggregate results to each location. For example, the remote system 74 may examine larger regions for common sensor data or trends in sensor data, and provide information on the identified commonality or environmental data trends to each local system 81, 82.

In situations in which the systems discussed here collect personal information about users, or may make use of personal information, the users may be provided with an opportunity to control whether programs or features collect user information (e.g., information about a user's social network, social actions or activities, profession, a user's preferences, or a user's current location), or to control whether and/or how to receive content from the content server that may be more relevant to the user. In addition, certain data may be treated in one or more ways before it is stored or used, so that personally identifiable information is removed. As another example, systems disclosed herein may allow a user to restrict the information collected by the systems disclosed herein to applications specific to the user, such as by disabling or limiting the extent to which such information is aggregated or used in analysis with other information from other users. Thus, the user may have control over how information is collected about the user and used by a system as disclosed herein.

Implementations of the presently disclosed subject matter may be implemented in and used with a variety of component and network architectures. FIG. 17 is an example computer 20 suitable for implementations of the presently disclosed subject matter. The computer 20 includes a bus 21 which interconnects major components of the computer 20, such as a central processor 24, a memory 27 (typically RAM, but which may also include ROM, flash RAM, or the like), an input/output controller 28, a user display 22, such as a display screen via a display adapter, a user input interface 26, which may include one or more controllers and associated user input devices such as a keyboard, mouse, and the like, and may be closely coupled to the I/O controller 28, fixed storage 23, such as a hard drive, flash storage, Fibre Channel network, SAN device, SCSI device, and the like, and a removable media component 25 operative to control and receive an optical disk, flash drive, and the like.

The bus 21 allows data communication between the central processor 24 and the memory 27, which may include read-only memory (ROM) or flash memory (neither shown), and random access memory (RAM) (not shown), as previously noted. The RAM is generally the main memory into which the operating system and application programs are loaded. The ROM or flash memory can contain, among other code, the Basic Input-Output system (BIOS) which controls basic hardware operation such as the interaction with peripheral components. Applications resident with the computer 20 are generally stored on and accessed via a computer readable medium, such as a hard disk drive (e.g., fixed storage 23), an optical drive, floppy disk, or other storage medium 25.

The fixed storage 23 may be integral with the computer 20 or may be separate and accessed through other interfaces. A network interface 29 may provide a direct connection to a remote server via a telephone link, to the Internet via an internet service provider (ISP), or a direct connection to a remote server via a direct network link to the Internet via a POP (point of presence) or other technique. The network interface 29 may provide such connection using wireless techniques, including digital cellular telephone connection, Cellular Digital Packet Data (CDPD) connection, digital satellite data connection, or the like. For example, the network interface 29 may allow the computer to communicate with other computers via one or more local, wide-area, or other networks, as shown in FIG. 18.

Many other devices or components (not shown) may be connected in a similar manner (e.g., document scanners, digital cameras, and so on). Conversely, all of the components shown in FIG. 17 need not be present to practice the present disclosure. The components can be interconnected in different ways from that shown. The operation of a computer such as that shown in FIG. 17 is readily known in the art and is not discussed in detail in this application. Code to implement the present disclosure can be stored in computer-readable storage media such as one or more of the memory 27, fixed storage 23, removable media 25, or on a remote storage location.

FIG. 18 shows an example network arrangement according to an implementation of the disclosed subject matter. One or more clients 10, 11, such as local computers, smart phones, tablet computing devices, and the like may connect to other devices via one or more networks 7. The network may be a local network, wide-area network, the Internet, or any other suitable communication network or networks, and may be implemented on any suitable platform including wired and/or wireless networks. The clients may communicate with one or more servers 13 and/or databases 15. The devices may be directly accessible by the clients 10, 11, or one or more other devices may provide intermediary access such as where a server 13 provides access to resources stored in a database 15. The clients 10, 11 also may access remote platforms 17 or services provided by remote platforms 17 such as cloud computing arrangements and services. The remote platform 17 may include one or more servers 13 and/or databases 15.

More generally, various implementations of the presently disclosed subject matter may include or be implemented in the form of computer-implemented processes and apparatuses for practicing those processes. The disclosed subject matter also may be implemented in the form of a computer program product having computer program code containing instructions implemented in non-transitory and/or tangible media, such as floppy diskettes, CD-ROMs, hard drives, USB (universal serial bus) drives, or any other machine readable storage medium, wherein, when the computer program code is loaded into and executed by a computer, the computer becomes an apparatus for practicing implementations of the disclosed subject matter. Implementations also may be implemented in the form of computer program code, for example, whether stored in a storage medium, loaded into and/or executed by a computer, or transmitted over some transmission medium, such as over electrical wiring or cabling, through fiber optics, or via electromagnetic radiation, wherein when the computer program code is loaded into and executed by a computer, the computer becomes an apparatus for practicing implementations of the disclosed subject matter. When implemented on a general-purpose microprocessor, the computer program code segments configure the microprocessor to create specific logic circuits. In some configurations, a set of computer-readable instructions stored on a computer-readable storage medium may be implemented by a general-purpose processor, which may transform the general-purpose processor or a device containing the general-purpose processor into a special-purpose device configured to implement or carry out the instructions.

Implementations may use hardware that includes a processor, such as a general-purpose microprocessor and/or an Application Specific Integrated Circuit (ASIC) that embodies all or part of the techniques according to embodiments of the disclosed subject matter in hardware and/or firmware. The processor may be coupled to memory, such as RAM, ROM, flash memory, a hard disk or any other device capable of storing electronic information. The memory may store instructions adapted to be executed by the processor to perform the techniques according to embodiments of the disclosed subject matter.

The foregoing description, for purpose of explanation, has been described with reference to specific implementations. However, the illustrative discussions above are not intended to be exhaustive or to limit implementations of the disclosed subject matter to the precise forms disclosed. Many modifications and variations are possible in view of the above teachings. The implementations were chosen and described in order to explain the principles of implementations of the disclosed subject matter and their practical applications, to thereby enable others skilled in the art to utilize those implementations as well as various implementations with various modifications as may be suited to the particular use contemplated.

1. A computer-implemented method performed by a data processing apparatus, the method comprising:
receiving a current magnetic field vector based on a strength and direction of a magnetic field detected by a magnetometer of an opening sensor disposed at an entry point;
comparing the current magnetic field vector to an initial magnetic field vector for the opening sensor;
determining that the current magnetic field vector differs from the initial magnetic field vector by at least a threshold amount; and
generating a signal indicating that the opening sensor has been tripped.

2. The computer-implemented method of claim 1, wherein the opening sensor comprises a magnet separate from a housing for a magnetometer sensor comprising the magnetometer.

3. The computer-implemented method of claim 1, wherein the opening sensor comprises a magnetometer unit with a magnet in the same housing as a magnetometer sensor.

4. The computer-implemented method of claim 1, wherein the initial magnetic field vector is based on a strength and direction of a magnetic field detected by the magnetometer when the entry point is closed.

5. The computer-implemented method of claim 4, wherein the magnetic field comprises a magnetic field from a magnet of the opening sensor and a geomagnetic field in the region of the magnet of the opening sensor.

6. The computer-implemented method of claim 1, wherein the current magnetic field vector is based on a strength and direction of a magnetic field detected by the magnetometer when the entry point is open.

7. The computer-implemented method of claim 1, wherein the current magnetic field vector comprises a magnetic field from a magnet of the opening sensor, the local geomagnetic field, and a magnetic field from a second magnet.

8. The computer-implemented method of claim 1, wherein determining that the current magnetic field vector differs from the initial magnetic field vector by at least a threshold amount comprises at least one of determining that the magnitude of the current magnetic field vector differs from the magnitude of the initial magnetic field vector by a threshold amount and determining that the direction of the current magnetic field vector differs from the direction of the initial magnetic field vector by a threshold amount.

9. The computer-implemented method of claim 1, wherein the entry point comprises at least one portion that has a magnetic permeability different than the magnetic permeability of air.

10. The computer-implemented method of claim 9, wherein the initial magnetic field vector is based on a strength and direction of a magnetic field from a magnet of the opening sensor and the geomagnetic field when the entry point is closed and a portion of the magnetic field from the magnet travels through a portion of the entry point with a magnetic permeability different than the magnetic permeability of air before reaching the magnetometer, and wherein the current magnetic field vector is based on a strength and direction of a magnetic field from the magnet of the opening sensor and the geomagnetic field when the entry point is open and the portion of the magnetic field from the magnet travels through the air before reaching the magnetometer.

11. An apparatus comprising:
a magnet adapted to be affixed to a first portion of an entry point; and
a magnetometer and a communications chipset disposed in a housing adapted to be affixed to a second portion of the entry point, wherein the magnetometer is a 3-axis magnetic sensor adapted to determine the strength and direction of a total magnetic field at the location of the magnetometer, and wherein the communication chipset is adapted to transmit the magnetic field vector to a computing device of a smart home environment.

12. The apparatus of claim 11, wherein the magnet does not need to be aligned with the housing comprising the magnetometer when the magnet is affixed to the first portion of the entry point and the housing is affixed to the second portion of the entry point.

13. The apparatus of claim 11, wherein the magnetometer is further adapted to generate a magnetic field vector based on the detected total magnetic field.

14. The apparatus of claim 13, further comprising a processor adapted to compare an initial magnetic field vector based on a detected total magnetic field when the entry point is closed with a current magnetic field vector based on a current detected total magnetic field.

15. An apparatus comprising:
a magnet disposed in a housing adapted to be affixed to a first portion of an entry point; and
a magnetometer and a communications chipset disposed in the housing, wherein the magnetometer is a 3-axis magnetic sensor adapted to determine the strength and direction of a total magnetic field at the location of the magnetometer, and wherein the communication chipset is adapted to transmit the magnetic field vector to a computing device of a smart home environment.

16. The apparatus of claim 15, wherein the housing is affixed to the first portion of the entry point with a pole of the magnet directed at a second portion of the entry point.

17. The apparatus of claim 16, wherein the housing is affixed to the first portion of the entry point such that a portion of the magnetic field from the magnet travels through the second portion of the entry point before reaching the magnetometer when the entry point is closed and travels through the air before reaching the magnetometer when the entry point is open.

18. The apparatus of claim 15, wherein the magnetometer is further adapted to generate a magnetic field vector based on the detected total magnetic field.

19. The apparatus of claim 15, further comprising a processor adapted to compare an initial magnetic field vector based on a detected total magnetic field when the entry point is closed with a current magnetic field vector based on a current detected total magnetic field.

20. A computer-implemented system for an opening sensor with magnetic field detection comprising:
an opening sensor comprising a magnetometer adapted to detect a magnetic field and generate a magnetic field vector based on the detected magnetic field, and a communications chipset adapted to communicate with a hub computing device; and
a hub computing adapted to receive a current magnetic field vector based on a strength and direction of a magnetic field detected by the magnetometer of the opening sensor, compare the current magnetic field vector to an initial magnetic field vector for the opening sensor, determine that the current magnetic field vector differs from the initial magnetic field vector by at least a threshold amount, generate a signal indicating that the opening sensor has been tripped.

21. The computer-implemented system of claim 20, wherein the hub computing device is further adapted to receive the initial magnetic field vector generated when the opening sensor is installed on an entry point and the entry point is closed.

22. The computer-implemented system of claim 20, wherein the opening sensor comprises a magnet separate from a housing for a magnetometer sensor comprising the magnetometer.

23. The computer-implemented system of claim 20, wherein the opening sensor comprises a magnetometer unit with a magnet in the same housing as a magnetometer sensor comprising the magnetometer.

24. The computer-implemented system of claim 20, wherein the hub computing device is further adapted to determine that the current magnetic field vector differs from the initial magnetic field vector by at least a threshold amount when the difference between the initial magnetic field vector and the current magnetic field vector is greater than a difference caused by one or more of a vibration of the magnetometer or magnet and a fluctuation in the geomagnetic field.

25. A system comprising: one or more computers and one or more storage devices storing instructions which are operable, when executed by the one or more computers, to cause the one or more computers to perform operations comprising:
receiving a current magnetic field vector based on a strength and direction of a magnetic field detected by a magnetometer of an opening sensor of an entry point;
comparing the current magnetic field vector to an initial magnetic field vector for the opening sensor;
determining that the current magnetic field vector differs from the initial magnetic field vector by at least a threshold amount; and
generating a signal indicating that the opening sensor has been tripped.
